(19) United States
(12) Patent Application Publication
(10) Pub. No.: US 2003/0146019 A1
(43) Pub. Date: Aug. 7, 2003

(54) Board and ink used for forming conductive pattern, and method using thereof

(76) Inventor: Hiroyuki Hirai, Minami-ashigara-shi (JP)

Correspondence Address: BURNS, DOANE, SWECKER & MATHIS, L.L.P., P.O. Box 1404, Alexandria, VA, 22313-1404, US

(21) Appl. No.: 10/300,647

(22) Filed: Nov. 21, 2002

(30) Foreign Application Priority Data
Nov. 22, 2001 (JP) 357407/2001
Aug. 9, 2002 (JP) 232366/2002
Aug. 26, 2002 (JP) 244597/2002

(51) Int. Cl. H05K 1/09

(52) U.S. Cl. 174/257

(57) ABSTRACT

A novel board and ink used for forming conductive pattern are disclosed. They comprise colloidal particles which comprise a metal or a composite metal having a specific resistance of 20 μΩ·cm or below at 20° C., and have an average particle size of 1 to 100 nm. A novel method for forming conductive pattern is also disclosed. The method comprises a step of irradiating said colloidal particles, thereby generating heat and fusing at least a part of the colloidal particles with the heat. The method can be applied to a production of printed circuit boards.

### TECHNICAL FIELD

The present invention relates to a board and an ink used for drawing of fine conductive pattern with laser light or near-field light, and a method for forming conductive pattern using thereof.

### RELATED ART

There are various known techniques for forming a conductive pattern on a substrate, examples of which include (1) a method by which a conductive film typically composed of silver or copper is formed by sputtering, vacuum deposition, electroless plating or the like on the entire surface of the substrate and the film is then patterned by photolithography and etching to thereby obtain a desired conductive pattern; (2) a method by which a desired pattern is directly formed by electroless plating or vacuum deposition through a mask; (3) a method by which a desired pattern is drawn on the substrate using a solder or conductive paste; and (4) a method by which an anisotropic conductive film is formed on a substrate, and then pressure-contacted according to a desired pattern. It is, however, rather difficult with these methods to rapidly form a fine conductive pattern on a micrometer or a smaller scale.

On the other hand, nano particles having a size of one to several hundreds nanometer is strongly expected for the development as a functional material which exhibits unique features such as quantum size effect. To exhibit the function, it is necessary to control arrangement structure of the particles as well as to reduce the particle size to a nanometer level. As one known method based on this point of view, there is a method for connecting the electrodes with a conductive Ag nano wire by depositing Ag reductively using DNA which bridges electrodes as a template (Nature, Vol. 391, 775(1998)). While the method is advantageous in that forming a fine conductive pattern, it suffers from a narrow applicable range of species of the nano particles, and a long time required for the fabrication thereof, which makes the method less payable on the commercial base.

There is another known method for forming a silver conductive pattern by jetting an ink containing silver using ink jet technology (D&M Online Nikkei Mechanical, Internet URL:http://dm.nikkeibp.co.jp/members/DM/DMNEWS/20020402/2/main.sht ml). Silver particle will, however, have a relatively larger surface area as the particle size decreases to as small as several tens nanometers, and will become more labile to oxygen-induced oxidation, so that increase in the resistivity will not be negligible. Such tendency was found to be strong in case of using copper nano particle.

### SUMMARY OF THE INVENTION

One object of the present invention is to provide a board and an ink used for conductive pattern drawing which ensure simple and rapid drawing of fine conductive pattern. Another object of the present invention is to provide a method for readily and rapidly producing substrate used for conductive pattern drawing, and a printed circuit board produced by such method.

One aspect of the present invention relates to a board used for forming conductive pattern, comprising a substrate and a layer thereon, said layer comprising colloidal particles which comprise a metal or a composite metal having a specific resistance of 20 μΩ·cm or below at 20° C., and have an average particle size of 1 to 100 nm.

The another aspect of the present invention relates to an ink used for forming conductive pattern, comprising 1 to 80 wt % of colloidal particles which comprise a metal or a composite metal having a specific resistance of 20 μΩ·cm or below at 20° C., and have an average particle size of 1 to 100 nm.

The another aspect of the present invention relates to a method for forming a conductive pattern, which comprises a step of irradiating a board comprising a substrate and a layer thereon, said layer comprising colloidal particles which comprise a metal or a composite metal having a specific resistance of 20 μΩ·cm or below at 20° C., and have an average particle size of 1 to 100 nm, with laser light or near-field light, thereby generating heat and fusing at least a part of the colloidal particles with the heat.

The another aspect of the present invention relates to a method for forming a conductive pattern, comprising a step of drawing a pattern on a substrate by supplying droplets of an ink comprising 1 to 80 wt % of colloidal particles which comprise a metal or a composite metal having a specific resistance of 20 μΩ·cm or below at 20° C., and have an average particle size of 1 to 100 nm said colloidal particles, and a step of irradiating the substrate having said pattern drawn thereon with laser light or near-field light, thereby generating heat and fusing at least a part of the colloidal particles with the heat, wherein a series of the steps is carried out under inert gas atmosphere.

The another aspect of the present invention relates to a method for producing a printed circuit board, which comprises a step of irradiating colloidal particles which comprise a metal or a composite metal having a specific resistance of 20 μΩ·cm or below at 20° C., and have an average particle size of 1 to 100 nm, with laser light or near-field light, thereby generating heat and fusing at least a part of the colloidal particles with the heat.

When the board according to the present invention, or a substrate having formed thereon a desired pattern with the ink according to the present invention is irradiated by laser light or so, the laser light or so is absorbed by the colloidal particles so as to fuse at least a part of the metal or composite metal being in a state of nano-particle (and/or so as to vaporize and/or decompose an adsorptive compound or a surfactant for the case where the nano particles have such organic compound on the surface thereof), which produces a metal or composite metal area in which the nano particles are bonded with each other, and allows the irradiated area to exhibit a high electric conductivity.

Since the metal or composite metal in a state of nano-particle shows a melting point considerably lower than that observed for the bulk state, the nano particles can readily be fused only with a relatively low energy so as to form a continuous structure, and only an irradiated area can exhibit electric conductivity. Moreover the present invention is advantageous in that forming a conductive pattern with a high resolution, since the colloidal particles employed herein are of nanometer scale. Using the board or the ink according to the present invention will therefore be successful in forming fine conductive pattern in a simple and rapid manner with a low energy laser light or the like.

It is to be noted now that the term “composite metal” should be understood in the broadest sense, and includes any materials which are composed of a plurality of metal. Examples of “composite metal” include materials being in states of core shell, inhomogeneous mixture, and the like. Metals included in composite metal may interact with each other, or exist independently.

### DETAILED DESCRIPTION OF THE INVENTION

[Board for Conductive Pattern Drawing, and a Method for Forming Conductive Pattern Using Thereof]

A feature of the board according to the present invention resides in that having a layer which contains colloidal particles. The colloidal particle employed in the present invention comprises a metal or a composite metal having a specific resistance of 20 μΩ·cm or below at 20° C. (more preferably 10 μΩ·cm or below, and still more preferably 6 μΩ·cm or below). The colloidal particle preferably fuses at low temperatures (preferably has a melting point of 150 to 1,500° C.). It is generally known that values for physical properties of metal or composite metal differ between the bulk state and nano-particle state, and the above-described ranges for the specific resistance and melting point refer to those for the bulk state, which can be found in literatures such as “Kagaku Binran (Handbook of Chemistry)”, edition of The Chemical Society of Japan) and “Bunseki Kagaku Binran (Handbook of Analytical Chemistry)”, edition of The Japan Society for Analytical Chemistry).

Examples of the metals which satisfy the above conditions include Au, Ag, Cu, Zn, Cd, Al, In, Tl, Sn, Co, and Ni. Of these, Au, Ag, Cu, Al, Zn, Sn, and In are preferable because of their low specific resistance and melting point. For the case where the colloidal particle comprises a composite metal, it is preferable to use a composite metal containing at least one metal selected from the group consisting of Au, Ag, Cu, Al, Zn, Sn and In. Examples of such composite metal include Cu—Zn, Cu—Sn, Al—Cu, Cu—Sn—Pd, Cu—Ni, Au—Ag—Cu, Au—Zn, Au—Ni, Ag—Cu—Zn, Ag—Cu—Zn—Sn, Sn—Pb, Ag—In, Cu—Ag—Ni, Ag—Pd and Ag—Cu, where the composite metal is by no means limited thereto. There is no specific limitation on the compositional ratio of the individual metals contained in the composite metal, and the ratio can properly be selected.

The metal or composite metal may contain impurities, where the content of the impurities is preferably suppressed to as low as less than 1%. Possible impurity elements include not only metals such as Fe, Cr, W, Sb, Bi, Pd, Rh, Ru and Pt, but also include non-metals such as P, B, C, N and S, alkaline metals such as Na and K, and alkaline earth metals such as Mg and Ca. These impurity elements may be contained independently or in any combination of two or more species.

The board according to the present invention comprises a layer comprising the foregoing colloidal particles. The layer may be formed by coating a colloidal dispersion liquid containing the colloidal particles which comprise the metal or composite metal, and then drying the coated liquid.

The colloidal dispersion liquid employed in the present invention contains the colloidal particles having an average particle size of 1 to 100 nm. The colloidal dispersion liquid can be obtained by preparing the nano particles which comprises a metal or composite metal, and then by dispersing them into a proper solvent. One typical method for preparing the nano particles of metal or composite metal is a gas-evaporation method which comprises heating a solid metal material placed in a crucible by high frequency wave induction heating, to thereby generate metal vapor, and cooling rapidly the generated metal vapor by collusion with gas molecules of He, Ar or the like to thereby produce the fine particles of metal or composite metal. The colloidal dispersion liquid may be prepared by dispersing the nano particles of a metal or composite metal in a proper solvent.

Another possible method for preparing the colloidal dispersion liquid relates to solution reduction process, in which the colloidal metal particles are obtained by the liquid phase reaction of a dissolved salt of one or more metals selected from the above with an inorganic or organic reducing agent (e.g., NaBH₄, hydrazine-base, amine-base or diol-base compound), with a metal having a smaller oxidation-reduction potential (e.g., magnesium), or with a metal salt having a smaller valence.

In the present invention, it is preferable to obtain the colloidal particles by the liquid-phase process (solution reduction method), in which metal ion is reduced with a reducing agent in liquid phase since the obtained colloidal dispersion may be in stable condition. It should be noted that metals in state of colloidal particles having a nano-order particle size are more readily oxidized by oxygen than metals in state of bulk since colloidal particles have large surface areas. Since metal oxides have high specific resistance, it is preferable to prevent metal particles from being oxidized by oxygen. My studies reveal that the oxidation of metal colloidal particles can be remarkably depressed by preparing the reaction solution using oxygen-free solvent under an inert gas atmosphere, and carrying out the solution reduction under an inert gas atmosphere.

It is preferable to preserve the colloidal dispersion liquid under an inert gas atmosphere.

Thus prepared colloidal dispersion liquid may directly be used as a coating liquid without any further processing, or may be used after being processed in various ways such as being concentrated, desalted, purified or diluted. These treatments may be preferably carried out under an inert gas atmosphere and the obtained coating liquid may be preferably preserved under an inert gas atmosphere. Examples of inert gases include N₂, He, Ne and Ar gas.

In the present invention, an average particle size of the colloidal particle falls within a range from 1 to 100 nm. The average particle size smaller than 1 nm will destabilize the particle, and will be more likely to result in coagulation during storage, coating or drying of the colloidal dispersion liquid. On the other hand, exceeding 100 nm will require a large energy in order to fuse the particles. Thus a range of the average particle size is preferably 2 to 80 nm, and more preferably 3 to 50 nm.

The average particle size of the colloidal particle can be measured under a transmission electron microscope (TEM).

Examples of dispersion solvent for the colloidal dispersion liquid include water; esters such as butyl acetate and cellosolve acetate; ketones such as methyl ethyl ketone, cyclohexanone, methyl isobutyl ketone and acetylacetone; chlorinated hydrocarbons such as dichloromethane, 1,2-dichloroethane and chloroform; amides such as dimethylformamide; aliphatic hydrocarbons such as cyclohexane, heptane, octane, isooctane and decane; aromatic hydrocarbons such as toluene and xylene; ethers such as tetrahydrofuran, ethyl ether and dioxane; alcohols such as ethanol, n-propanol, isopropanol, n-butanol, diacetonealcohol, ethyleneglycol, cyclohexanol cyclopentanol and cyclohexenol, 2,5-hexanediol; fluorine-containing solvents such as 2,2,3,3-tetrafluoropropanol; glycol ethers such as ethyleneglycol monomethyl ether, ethyleneglycol monomethyl ether and propyleneglycol monomethyl ether; and alkylamino alcohols such as 2-dimethylaminoethanol, 2-dietylaminoethanol, 2-dimethylamino-isopropanol, 3-diethylamino-1-propanol, 2-dimethylamino-2-methyl-1-propanol, 2-methylaminoethanol, and 4-dimethylamino-1-butanol. These solvents may be used independently or in any combination of two or more species in consideration of dispersibility of the colloidal particle or anti-oxidative stability.

The colloidal dispersion liquid preferably contains an organic compound such as adsorptive compound (dispersant) or surfactant. The adsorptive compound and surfactant typically adsorbs on the surface of the colloidal particles to thereby modify the surface thereof, which contributes to improvement in the stability of the colloidal dispersion liquid and assurance of insulation property of the colloidal particle. The colloid may be hydrophilic or may be hydrophobic. Effective adsorptive compounds are those containing any of functional groups selected from —SH, —CN, —NH₂, —SO₂OH, —SOOH, —OPO(OH)₂ and —COOH, where those containing —SH or —COOH are especially preferable. For the case where the colloid has a hydrophilic property, it is preferable to use an adsorptive compound having a hydrophilic group such as —SO₃M and —COOM (where, M represents hydrogen atom, alkaline metal atom or ammonium). It is also preferable for the colloidal dispersion liquid to contain an anionic surfactant (e.g., sodium bis(2-ethylhexyl)sulfosuccinate and sodium dodecylbenzenesulfonate), nonionic surfactant (e.g., alkyl ester of polyalkyl glycol and alkylphenyl ether), fluorine-containing surfactant, and hydrophilic polymer (e.g., hydroxyethyl cellulose, polyvinylpyrrolidone, polyvinylalcohol and polyethylene glycol).

For the case where the colloidal particle is synthesized by the liquid-phase process, use of a reducing agent under the presence of the foregoing adsorptive agent is preferable in view of obtaining a stable colloidal dispersion liquid.

Organic compounds such as the foregoing adsorptive compounds are preferably used in a ratio by weight 0.01 to 2 times the amount of the metal or composite metal, and more preferably 0.05 to 1 times. The ratio by weight of less than 0.01 times will tend to degrade the insulating property between any colloidal particles. On the other hand, exceeding 2 times will tend to make it difficult to achieve a sufficient conductivity even if the colloidal particles are irradiated with laser light or near-field light. The organic compound preferably covers the surface of the colloidal particle in a thickness of 1 to 10 nm. It is not always necessary for the organic compound to uniformly cover the colloidal particle, where only a partial coverage over the surface thereof is also allowable.

Actual state of the surface of the colloidal particle covered with an organic compound is viewable under a high-resolution TEM such as FE-TEM, which is proved by a regular gap observed between any adjacent particles, and can be confirmed by chemical analysis.

The colloidal dispersion liquid may further be added with, other than organic compounds such as the foregoing adsorptive compounds, various additives such as antistatic agent, antioxidant, UV absorber, plasticizer, polymer binder, carbon nano-particle and dye depending on purposes.

The colloidal dispersion liquid may be preferably used as a coating liquid after removing an unnecessary portion of salts contained therein by desalting process such as centrifugal separation, electric dialysis and ultrafiltration. The colloidal dispersion liquid available as a coating liquid preferably has an electric conductivity of 1,000 μS/cm or below, and more preferably 100 μS/cm or below at 25° C.

The layer (sometimes referred to as “fine particle layer” in the specification) can be formed by coating the foregoing colloidal dispersion liquid on a substrate and then by drying. There is no specific limitation on the coating method, where any of spin coating, dip coating, extrusion coating and bar coating is available. While the thickness (dried state) of the layer is not specifically limited, a preferable range is 5 to 10,000 nm, and more preferable range is 10 to 5,000 nm.

While the amount of metal or composite metal in the fine particle layer is not specifically limited, a preferable range is 10 to 100,000 mg/m², and more preferable range is 20 to 50,000 mg/m².

Materials for composing the substrate available in the present invention include glasses such as quartz glass, alkaline-free glass, crystallized transparent glass, Pyrex glass and sapphire glass; inorganic materials such as Al₂O₃, MgO, BeO, ZrO₂, Y₂O₃, ThO₂, CaO and GGG (gadolinium-gallium-garnet); polycarbonate; acrylic polymers such as polymethyl methacrylate; vinyl chloride polymers such as polyvinyl chloride and vinyl chloride copolymer; epoxy resin; polyarylate; polysulfone; polyether sulfone; polyimide; fluorine-containing polymers; phenoxy polymers; polyolefin-base polymers; nylon; styrene-base polymers; ABS polymers and metal, which may be used in arbitrary combinations as desired. These materials are properly selected in consideration of applications, and can be fabricated in a form of flexible substrate such as film, or rigid substrate. The substrate may have any of a disc form, card from and sheet form, and even may have a three-dimensional stacked form.

The board according to the present invention may have an underlying layer between the substrate and the layer for the purpose of improving flatness of the substrate, improving adhesion and preventing the fine particle layer from changing quality. Source materials for the underlying layer include polymer materials such as polymethyl methacrylate, acrylate-methacrylate copolymer, styrene-maleic anhydride copolymer, polyvinyl alcohol, N-methylolacrylamide, styrene-vinyltoluene copolymer, chlorosulfonated polyethylene, nitrocellulose, polyvinyl choloride, polyvinylidene choloride, chlorinated polyolefin, polyester, polyimide, vinyl acetate-vinyl chloride copolymer, ethylene-vinyl acetate copolymer, polyethylene, polypropylene and polycarbonate; thermosetting, photo-curing, or electron beam-curing resins; surface modifications such as coupling agent; and colloidal silica. The source materials are preferably excellent in adhesiveness both to the substrate and the layer, and specific examples thereof include thermosetting, photo-curing, or electron beam-curing resins; coupling agents (e.g., silane coupling agent, titanate-base coupling agent, germanium-base coupling agent and aluminum-base coupling agent); and colloidal silica.

The underlying layer can be formed first by preparing a coating liquid by dissolving or dispersing the foregoing materials into a proper solvent, and then by spreading the coating liquid over the surface of the substrate by any of known coating techniques of spin coating, dip coating, extrusion coating and bar coating. The film thickness (dried state) of the underlying layer preferably falls within a range from 0.001 to 20 μm in general, and more preferably falls within a range from 0.005 to 10 μm.

Next paragraphs will deal with a method of forming conductive pattern using the board according to the present invention.

One embodiment of the method for forming conductive pattern according to the present invention comprises a step of irradiating the fine particle layer which contains the colloidal particles of a metal or composite metal with laser light or near-field light. The light may be absorbed by the colloidal particles or other additives and converted to heat. At least a part of the colloidal particles may fuse by the generated heat to bond with each other to thereby exhibit electric conductivity in the irradiated portion. For the case where the surface of the colloidal particles is modified with an organic compound such as an adsorptive compound (dispersant) or surfactant, such organic compound covering the surface of the colloidal particles to vaporize and/or decompose by the generated heat.

Since the nano-sized colloidal particle has a melting point considerably lower than that of the bulk material, the method for forming conductive pattern according to the present invention is advantageous in that ensuring quick drawing at a relatively low energy. The laser light or near-field light is preferably irradiated from the fine particle layer side.

A portion of the layer other than the portion composing the pattern may be removed typically using a proper solvent. The board after the removal of the portion other than that composing the pattern may be subjected to post-processing such as annealing.

Wavelength of the laser light used for the method for forming conductive pattern according to the present invention can arbitrarily be selected over a range from ultraviolet to infrared radiation so far as the light can be absorbed by the colloidal particles, dispersant, or by carbon nano-particle or dye optionally added to the colloidal dispersion liquid. Representative lasers include semiconductor lasers such as AlGaAs laser, InGaAsP laser and GaN laser; Nd:YAG laser; excimer lasers such ArF laser, KrF laser and XeCl laser; dye lasers; solid lasers such as Ruby laser; gas lasers such as He-Ne laser, He-Xe laser, He-Cd laser, CO₂ laser and Ar laser; and free electron lasers. It is also allowable to use secondary or tertiary harmonic wave of these lasers. Either continuous or at least one pulse irradiation may be carried out by the lasers. Although it is difficult to generally describe the irradiation energy since it depends on metal species and size of the colloidal particles, thickness of the layer, and species and amount of the dispersant or binder, the energy is set so that the metal nano-particle can properly be fused without substantially ablation.

The method for forming conductive pattern according to the present invention can also employ near-field light generated by various forms of probe. A near-field-light probe of floating slider type having a built-in semiconductor laser device is disclosed in JP-A (term “JP-A” as used herein means an “unexamined published Japanese patent application) No. 10-255320, a planar-type probe head in disclosed in JP-A No. 2000-149303, and an improved design for enhancing metal plasmon in disclosed in JP-A Nos. 2001-67668 and 2000-23172. A preferable probe is such that having in the head portion thereof a built-in semiconductor laser oscillator, and it is more preferable to have an array-type contact head arranged in a two-dimensional manner. While it is generally pointed out that near-field light suffers from a relatively slow speed in writing operation, employment of micro-arrays in the number of 100 to 10,000 or around arranged in a two-dimensional manner can ensure a high transmission rate. Since the near-field light generally has only a weak light intensity, it is critical to coat the end portion of the probe with a metal so as to ensure effective coupling with surface plasmon. While the metal coating is preferably provided to a condensing prism portion on the end of the probe, some cases may require another strategy for enhancing condensation of near-field light by leaving a part of the surface of the end prism uncoated, which depends on morphology of the probe. Near-field light is preferably generated from the end of the micro-array, where wavelength of laser light from the built-in laser oscillator can arbitrarily be selected over a range from ultraviolet to infrared radiations.

Since intensity of light generally decays in an exponential manner as the point of observation becomes further from the light source, the light source of near-field light is preferably placed within a distance of 100 nm from the fine particle layer. For the case where the output of the micro-array head is typically set in a practical range, the distance exceeding 100 nm will make it difficult to provide heat necessary for deforming the fine particle layer, and the distance less than 5 nm will vitiate the practical feature since the end portion of the probe will be more likely to contact with the board and to be damaged. It is also desirable to mount the head on a platform and adjust the legs of the platform so as to contact with the surface of the board, and further to provide a lubricant layer (e.g. layer of fluorine-containing oil such as perfluoropolyethyldiol) of 1 to 10 nm thick on the surface of the board.

[Ink used for Conductive Pattern Drawing and a Method for Forming Conductive Pattern Using Thereof]

A specific feature of the ink according to the present invention resides in that containing the colloidal particles which comprise a metal or a composite metal having a specific resistance of 20 μΩ·cm or below at 20° C., and have an average particle size of 1 to 100 nm. Specific examples of the metal and composite metal composing the colloidal particles are same with those composing the colloidal particles used for producing the board according to the present invention. It is to be strongly recommended for the ink to employ metal or composite metal which is less likely to cause electrophoretic migration and has a small specific resistance. From this point of view, it is preferable to use at least either Ag or Cu, or a composite metal containing at least one of such metals.

The ink of the present invention preferably comprises a colloidal dispersion liquid containing 1 to 80 wt %, preferably 1 to 50 wt %, of colloidal particles which comprise at least a metal or a composite metal. Content of the colloidal particles of less than 1 wt % will fail in obtaining a sufficient level of electric conductivity, and exceeding 80 wt % will tend to cause clogging of a nozzle when an ink-jet printer is used for supplying droplets of the ink. The colloidal dispersion liquid can be prepared by a method comprising a step of dispersing nano particles into a proper solvent, after or while producing the nano particles. The method for preparing the colloidal dispersion liquid is same as that described for the colloidal dispersion liquid used for preparing the fine particle layer of the board according to the present invention. Preparation of the colloidal dispersion liquid by the liquid-phase process (solution reduction method), by which metal ion is reduced with a reducing agent in oxygen-free solution under an inert gas atmosphere, is particularly preferable in terms of preparing a desirable colloidal dispersion liquid. The dispersion of colloidal particles obtained by said liquid phase process may be subjected to at least one of desalting, concentration, purification and dilution in order to prepare the ink. These treatments are preferably carried out under an inert gas atmosphere. Or the colloidal dispersion liquid obtained by said liquid phase process may directly be used as an ink without any further treatments.

Other features of the process are same as those described for the colloidal dispersion liquid used for forming the fine particle layer of the board according to the present invention, which features include desirable range of average particle size of the colloidal particle contained in the ink; specific examples of solvent available for the dispersion liquid; specific examples and desirable range of contents of the adsorptive compound (dispersant) or surfactant which modifies the surface of the colloidal particles through adsorption or so, to thereby raise the stability of the colloidal dispersion liquid.

The colloidal dispersion liquid may be used as the ink after being added with, besides the foregoing organic compounds such as the adsorptive compounds, various additives such as antistatic agent, antioxidant, UV absorber, plasticizer, polymer binder, carbon nano-particle and dye depending on purposes, and after being properly adjusted in physical properties thereof. An unnecessary portion of salts contained in the colloidal dispersion liquid may be removed under an inert gas atmosphere by any of desalting process such as centrifugal separation, electric dialysis and ultrafiltration. Electric conductivity of the ink is preferably suppressed to 1,000 μS/cm or below, and more preferably 100 μS/cm or below at 25° C. Viscosity of the ink preferably falls within a range from 1 to 100 cP, more preferably 1 to 20 cP, at 25° C.

Next paragraphs will deal with the method for forming conductive pattern using the ink used for conductive pattern drawing according to the present invention.

One embodiment of the method for forming conductive pattern according to the present invention is such that supplying droplets of the ink of the present invention on the substrate to thereby draw a pattern on such substrate; irradiating the substrate having said pattern drawn thereon with laser light to thereby generate heat, and fusing at least a portion of the colloidal particle with such generated heat to thereby form a conductive pattern, where a series of these steps is carried out under an inert gas atmosphere.

A step of drying the substrate, having said pattern drawn thereon, with infrared light (including infra-red lasers) or a heating device may be carried out between the supplying step and irradiating step, in order to remove a solvent. Or the drying step may be carried out while the irradiating step being carried out using the laser. In such case, the kind of laser and the way of irradiating used in the drying step may be same as or different from that used in the irradiating step.

Formation of the pattern while supplying the droplets of the ink is successfully accomplished by using an ink-jet printer. There are various types of ink-jet printers classified based on ink jet mechanism, which types include piezoelectric type, bubble-jet type, air flow type, those using solid thermal fusing ink, static induction type, acoustic ink printing type, those using electro-viscous ink, and continuous injection type which is suitable for mass production, where any of which is available for the present invention after being properly selected in consideration of morphology and thickness of the pattern, and species of the ink. The ink-jet system is advantageous in that reducing the pattern width or pitch to as small as 10 μm or around by properly controlling size of the ink droplets to be ejected. It is fully possible to apply the system to formation of circuit pattern. Connecting of the ink-jet printer with a computer such as a personal computer allows drawing of conductive pattern on the substrate based on graphic information stored therein. It is also feasible to draw a conductive pattern and insulation pattern at the same time as described in the Japanese Unexamined Patent Publication No. 11-163499. In this case, the conductive portion and insulating portion preferably have an equivalent film thickness (dried thickness). The thickness of the conductive pattern can be set within a range from 0.1 to 10 μm in consideration of applications.

Thus the present invention is successful in pattern formation within a considerably shorter time than in the conventional process in which an conductive film is patterned through a photo resist mask.

Next, laser light is irradiated to the substrate having already formed thereon the pattern which comprises the nano-particle colloid. The laser light is absorbed by the colloidal particles, dispersant, or by carbon nano-particle or dye optionally added to the colloid dispersion liquid, so as to fuse at least a part of the metal or composite metal which exist in a nano-particle form (or so as to vaporize and/or decompose an adsorbed organic compound for the case where the nano-particle has such organic compound on the surface thereof), which produces metal or composite metal portion in which the nano particles are bonded with each other, and allows the irradiated area to exhibit a high electric conductivity. Since the metal or composite metal in a form of nano-particle shows a melting point considerably lower than that observed for the bulk state, the nano particles can readily be fused only with a relatively low energy so as to form a continuous structure, and only an irradiated area can exhibit electric conductivity. Moreover the present invention is advantageous in that forming a conductive pattern with a high resolution, since the colloidal particles employed herein are of nanometer scale. Using the method for forming conductive pattern according to the present invention will therefore be successful in forming fine conductive pattern only with a low-energy laser.

It is to be noted that the metal nano-particle is highly labile to oxygen-induced oxidation, so that a series of process steps which include ink preparation step, ink-jet drawing step and laser irradiation step must be carried out under an inert gas atmosphere. This successfully yields a high-conductivity pattern. The inert gas herein is exemplified by nitrogen, helium, neon and argon.

In the present invention, any wavelength of laser light, ranging from infrared radiation through visible light to ultraviolet radiation, is available so far as the light can be absorbed by the nano-particle colloid, dispersant, or by carbon nano-particle or dye optionally added. Representative lasers include semiconductor lasers such as AlGaAs laser, InGaAsP laser and GaN laser; Nd:YAG laser; excimer lasers such ArF laser, KrF laser and XeCl laser; dye lasers; solid lasers such as Ruby laser; gas lasers such as He—Ne laser, He—Xe laser, He—Cd laser, CO₂ laser and Ar laser; and free electron lasers. It is allowable to use planar-emission semiconductor laser device, or multi-mode array having such laser devices arranged in a linear or two-dimensional manner. It is still also allowable to use a higher-order harmonic wave such as secondary or tertiary harmonic wave of the laser emission. The lasers may be irradiated either in a continuous manner or pulsated and multiple manner. Although it is difficult to generally describe the irradiation energy since it depends on metal species and size of the colloidal particle, thickness of the fine particle layer, and species and amount of the dispersant, binder or solvent, the energy is set so that the metal nano-particle can properly be fused without being substantially abraded.

Also in this embodiment, near-field light generated by various forms of probe is available as previously described with regard to the method for forming conductive pattern using the board which is used for conductive pattern drawing according to the present invention, where details of the near-field light are as described in the above.

Source materials for composing the substrate are same as those specifically described with regard to the board according to the present invention. The substrate may have a underlying layer on the surface to which the ink is supplied for the purpose of absorbing solvent in the ink, improving smoothness of the substrate surface, improving adhesive force and preventing the fine particle layer from being denatured. All of source materials for composing the underlying layer, method for forming the layer and the thickness thereof are same as those specifically described for the underlying layer provided on the substrate of the board according to the present invention.

The method for forming conductive pattern using the board or ink according to the present invention is not only suitable for producing printed-wiring board for LCD (liquid-crystal display), EL (electro-luminescent) display and electronic paper, but also for producing substrate used for electroless plating or electrolytic plating.

### EXAMPLES

### Example 1

(Preparation of Cu—Ag—Ni Colloidal Dispersion Liquid)

Solution “A-1” was prepared by dissolving 4 g of copper acetate monohydrate, 2.5 g of nickel acetate tetra hydrate, 1.7 g of silver nitrate, 1 mL of acetic acid and 7.2 g of polyvinylpyrrolidone (K-15) in 800 mL of deoxygenated water. On the other hand, solution “B-1” was prepared by dissolving 2.7 g of sodium borohydride (NaBH₄) into 50 mL of deoxygenated water. While stirring solution “A-1” in an argon box, the whole volume of solution “B-1” was added thereto. The mixture showing a slight bubbling was kept under stirring for 30 minutes to thereby yield a brownish black reaction liquid. The reaction liquid was then concentrated to a volume of approx. 100 mL by ultrafiltration. The obtained concentrate was added with 400 mL of water, again concentrated to approx. 100 mL by repeating ultrafiltration, finally added with 200 mL of water and 200 mL of 2-ethoxyethanol and then concentrated to approx. 100 mL by ultrafiltration, to thereby obtain a colloidal dispersion liquid.

Thus obtained colloidal dispersion liquid was found to have an electric conductivity of 18 μS/cm, composition of the colloidal particle of Cu:Ag:Ni=51:26:23 (ICP analysis), and a metal content of 2.6 wt %. FE-TEM observation revealed that an average size of the colloidal particles was approx. 8 nm, where the individual particles were isolated at regular intervals and contained Cu—Ag—Ni composite metal. Chemical analysis of the colloidal dispersion liquid also revealed that the liquid contained polyvinylpyrrolidone in a weight ratio to metal of 0.23.

(Producing of Board (1) Used for Conductive Pattern Drawing)

A 20 wt % solution of aminopropyltriethoxysilane, which is a silane coupling agent, in a mixed solvent of 2-ethoxyethanol and water (95:5 by weight) was coated on a resin base plate (100 mm×100 mm, 0.6 mm thick) made of polycarbonate (trade name: Panlite AD5503, product of Teijin Chemicals, Ltd.), and dried so as to form an underlying layer of 20 nm thick. On the underlying layer, the foregoing Cu—Ag—Ni colloidal dispersion liquid was coated, and dried so as to form a fine particle layer of 100 nm thick, to thereby obtain a Board (1) used for conductive pattern drawing.

(Drawing on Board (1) for Conductive Pattern Drawing)

On the Board (1), laser light having a wavelength of 405 nm was irradiated using a laser oscillator (product of Nichia Corporation), having an output of 12 mW and a spot diameter of 600 nm, at a linear velocity of 5 m/sec. Laser microscopic observation revealed that the colloidal particle fused to form a continuous layer at the irradiated portion. A separate experiment was made on the Board (1), where the entire surface of which was irradiated with the laser light, and showed that surface resistivity along the laser scanning direction was 2 Ω/□, and that along the direction normal thereto was 35 Ω/□. Surface resistivity of a non-irradiated board was found to be 10⁷ Ω/□ or above. It was confirmed that the conductive pattern can readily be formed by laser irradiation.

### Example 2

Near-field light was irradiated on the Board (1) for conductive pattern drawing using a probe (with a silver light-shield coating, end opening of 50 nm in diameter) which was fabricated according to a method described in Example 1 of Japanese Unexamined Patent Publication No. 2001-56279, and using a semiconductor laser device having an oscillation wavelength of 405 nm. Laser microscopic observation revealed that the colloidal particles fused to form a continuous layer at the irradiated portion.

It was thus found that the conductive pattern could also be drawn on the Board (1) by through near-field light irradiation.

### Example 3

The foregoing Cu—Ag—Ni colloidal dispersion liquid was further added with polyvinylpyrrolidone (K-15) so that the polyvinylpyrrolidone is contained in a ratio by weight of 3 relative to the metal. A Board (2) for conductive pattern drawing was produced similarly to Example 1 except that thus-obtained dispersion liquid was used for forming the fine particle layer. The Board (2) was subjected to laser irradiation similarly to Example 1, which revealed that the colloidal particles partially failed in forming the continuous layer and thus only showed an insufficient electric conductivity in the discontinuous area. Lowering the linear velocity of the laser to as slow as 0.5 m/sec was however successful in obtaining an almost uniform continuous layer at the laser-irradiated area, an in exhibiting electric conductivity.

### Example 4

An Ag—In colloid (7 nm), an Au—Ag—Cu colloid (4 nm), a Ni—Sn colloid (10 nm) and an In-Sn colloid (8 nm) were respectively prepared by the NaBH₄ reduction process similarly to the Cu—Ag—Ni colloidal dispersion liquid described in Example 1; an Ag colloid (5 nm) was prepared by the FeSO₄ reduction process; and the boards for conductive pattern drawing were then produced using the individual colloidal liquids. All of the boards were confirmed to have conductive pattern formed thereon. It is to be noted that numerals in the parentheses above represent average particle size.

### Example 5

(Producing of Board (3) used for Conductive Pattern Drawing)

A Board (3) used for conductive pattern drawing was produced similarly to Example 1, except that a glass base plate was used in place of the resin base plate used for producing the Board (1) for conductive pattern drawing in Example 1, and that the underlying layer was formed using tetraethoxyorthosilane prepolymer in place of aminopropyltrimethoxysilane, which is a silane coupling agent.

It was confirmed that the conductive pattern could also be drawn on the Board (3) by laser irradiation similarly to Example 1.

### Example 6

(Preparation of Copper Colloidal Dispersion Liquid)

Solution “A-2” was prepared by dissolving 13.5 g of copper chloride, and 20 g of polyvinylpyrrolidone (average molecular weight=3,000) in 600 mL of deoxygenated methanol. On the other hand, solution “B-2” was prepared by dissolving 7.5 g of sodium borohydride (NaBH₄) into 200 mL of deoxygenated methanol. While stirring solution “A-2” in an argon box, the whole volume of solution “B-2” was added thereto. The mixture showing a slight bubbling was kept under stirring for 30 minutes to thereby yield a brownish black reaction liquid. The reaction liquid was then concentrated to a volume of approx. 100 mL by ultrafiltration. The obtained concentrate was added with 500 mL of deoxygenated methanol, again concentrated to approx. 100 mL by ultrafiltration. This process was further repeated one more time, the obtained concentrate was finally added with 30 mL of deoxygenated 2-ethoxyethanol and 10 mL of ethylene glycol, and then blown with nitrogen gas to vaporize the solvent, to thereby obtain 40 mL of a colloidal dispersion liquid.

ICP and XD analyses revealed that the obtained colloidal dispersion liquid contained 12 wt % of Cu (crystallite size=5 nm). FE-TEM observation of the colloidal dispersion liquid revealed that the individual particles were isolated at regular intervals, and chemical analysis further revealed that the colloidal dispersion liquid contained polyvinylpyrrolidone in a weight ratio to Cu of 0.35. The Cu colloid dispersion liquid was packed into a cartridge in the argon box, which is to be used as a Cu ink (viscosity=10.5 cP).

(Drawing of Conductive Pattern)

A polyimide base plate (100 mm×100 mm, 0.6 mm thick) was subjected to UV-ozone treatment, a 20 wt % solution of aminopropyltriethoxysilane, which is a silane coupling agent, in a mixed solvent of 2-ethoxyethanol and water (95:5 by weight) was coated thereon, and dried so as to form an underlying layer of 200 nm thick. The foregoing Cu ink cartridge was set to a piezoelectric-type, ink-jet printer and the ink was ejected onto the underlying layer in a nitrogen atmosphere, to thereby draw a pattern.

(Formation of Conductive Pattern)

The substrate having drawn thereon the pattern was irradiated under a nitrogen atmosphere with 10 pulses of excimer laser light (300 Hz) having a wavelength of 308 nm, an output of 6 mJ/cm² and a pulse width of 20 nsec. Observation under a scanning electron microscope (UHR-SEM) revealed that the colloidal particles fused to form a continuous layer at the irradiated portion. Surface resistivity was measured as 0.05 Ω/□. Surface resistivity of a non-irradiated substrate was found to be 10⁷ Ω/□ or above. It was thus confirmed that the conductive pattern can readily be formed by laser irradiation.

### Example 7

The substrate having drawn thereon the pattern was irradiated again under a nitrogen atmosphere with a semiconductor laser light having a wavelength of 405 nm and an output of 4 mW. UHR-SEM observation revealed that the colloidal particle fused to form a continuous layer at the irradiated portion.

### Comparative Example 1

Drawing of a pattern using the ink-jet printer and formation of the conductive pattern with the aid of the excimer laser as described in Example 6 were carried out in the air, which revealed a surface resistivity of 2×10² Ω/□. XD analysis of the pattern showed formation of copper oxide. UHR-SEM observation showed that continuous layer was formed only to an insufficient degree.

### Example 8

An Ag colloidal dispersion liquid, an Ag(70 at %)-Pd(30 at %) colloidal dispersion liquid, an Ag(50 at %)-Cu(50 at %) colloidal dispersion liquid, and a Cu(70 at %)-Ni(30 at %) colloidal dispersion liquid were respectively prepared by the solution reduction process similarly to the Cu colloidal dispersion liquid described in Example 6, and patterns were drawn in the nitrogen atmosphere respectively using thus-obtained colloidal dispersions and the ink-jet printer. It was confirmed that the conductive patterns were successfully formed by excimer laser irradiation similarly to Example 1.

### Example 9

A pattern was drawn in the nitrogen atmosphere using the ink-jet printer similarly to Example 6, except that a glass base plate was used in place of the polyimide resin base plate in Example 6, and that the underlying layer was formed using tetraethoxyorthosilane prepolymer in place of aminopropyltrimethoxysilane which is a silane coupling agent. It was confirmed that a Cu conductive pattern was successfully formed by excimer laser irradiation.

### Example 10

A Cu colloidal dispersion liquid was prepared similarly to Example 6, except that a standard methanol was used in place of the deoxygenated methanol and the reaction was carried out under room air. The XD analysis of the obtained liquid revealed that the liquid contained not only Cu metal but also CuCl and Cu₂O. This result suggests that the Cu colloidal dispersion liquid should be prepared with deoxygenated solvent under a deoxygenated atmosphere.

### Example 11

(Preparation of Copper Colloidal Dispersion Liquid without Deionization)

Solution “A-3” was prepared by dissolving 3.78 g of copper acetate hydrate in 200 mL of deoxygenated 2-diethylaminoethanol at 50° C. On the other hand, solution “B-3” was prepared by dissolving 1.1 g of hydrazine hydrate into 20 mL of deoxygenated 2-diethylaminorthanol. While stirring solution “A-3” with forced aeration using nitrogen gas, the 10 mL of solution “B-3” was added thereto. The mixture showing a slight bubbling was kept under stirring for 1 minute to thereby yield a brownish black reaction liquid. The reaction liquid was then concentrated by ultrafiltration, thereby being obtained a 10.0 wt % of copper colloidal dispersion liquid, which contains particles having an average particle size of about 8 nm.

A cartridge was filled with an ink having a viscosity of 8 cP, which was prepared by adding ethylene glycol to the obtained copper colloidal dispersion liquid so as to control the viscosity, in an argon box. And patterns were drawn in the nitrogen atmosphere respectively using the ink-jet printer in the same way to Example 6. It was confirmed that the conductive patterns of copper having high conductivity were successfully formed by laser irradiation.

As has been described in the above, the present invention can provide a board and an ink used for conductive pattern drawing with which a fine conductive pattern can be drawn. The present invention is also successful in providing a method for forming a conductive pattern in a simple and rapid manner, and the printed-wiring board produced by such method. In particular, using the ink for conductive pattern drawing and an ink-jet printer allows on-demand production of a printed-wiring board.

Having described our invention as related to the present embodiments, it is our intention that the invention not be limited by any of the details of the description, unless otherwise specified, but rather be construed broadly within its spirit and scope as set out in the accompanying claims.

What is claimed is:

1. A board used for forming conductive pattern, comprising a substrate and a layer thereon, said layer comprising colloidal particles which comprise a metal or a composite metal having a specific resistance of 20 μΩ·cm or below at 20° C., and have an average particle size of 1 to 100 nm.

2. The board of claim 1, wherein the layer comprises an adsorptive compound or a surfactant in a ratio by weight 0.01 to 2 times the amount of the metal or composite metal.

3. The board of claim 1, further comprising an underlying layer between said layer and the substrate.

4. The board of claim 1, wherein the metal is a metal selected from the group consisting of Au, Ag, Cu, Al, Zn, Sn and In, or the composite metal comprises a metal selected from said group.

5. An ink used for forming conductive pattern, comprising 1 to 80 wt % of colloidal particles which comprise a metal or a composite metal having a specific resistance of 20 μΩ·cm or below at 20° C., and have an average particle size of 1 to 100 nm.

6. The ink of claim 5, wherein the metal is either Ag or Cu, or the composite metal comprises Ag and/or Cu.

7. The ink of claim 5, wherein the colloidal particles are such that being obtained by liquid-phase process in which at least one metal ion is reduced by a reducing agent in an oxygen-free solution under an inert gas atmosphere.

8. The ink of claim 7, wherein a dispersion of the colloidal particles is subjected to at least one of desalting, concentration, purification and dilution.

9. The ink of claim 5, which further comprises an adsorptive compound or a surfactant in a ratio by weight 0.01 to 2 times the amount of the metal or composite metal.

10. The ink of claim 5, which has a viscosity of 1 to 100 cP at 25° C.

11. A method for forming a conductive pattern, which comprises a step of irradiating a board comprising a substrate and a layer thereon, said layer comprising colloidal particles which comprise a metal or a composite metal having a specific resistance of 20 μΩ·cm or below at 20° C., and have an average particle size of 1 to 100 nm, with laser light or near-field light, thereby generating heat and fusing at least a part of the colloidal particles with the heat.

12. The method of claim 11, wherein the board further comprises an underlying layer between said layer and the substrate.

13. The method of claim 11, wherein the metal is either Ag or Cu, or the composite metal comprises Ag and/or Cu.

14. A method for forming a conductive pattern, comprising a step of drawing a pattern on a substrate while supplying droplets of an ink comprising 1 to 80 wt % of colloidal particles which comprise a metal or a composite metal having a specific resistance of 20 μΩ·cm or below at 20° C., and have an average particle size of 1 to 100 nm; and a step of irradiating the substrate having said pattern drawn thereon with laser light or near-field light, thereby generating heat and fusing at least a part of the colloidal particles with the heat, wherein a series of the steps is carried out under an inert gas atmosphere.

15. The method of claim 14, wherein the substrate comprises an underlying layer, on the surface of which the ink is supplied.

16. The method of claim 14, wherein the metal is either Ag or Cu, or the composite metal comprises Ag and/or Cu.

17. The method of claim 14, wherein the colloidal particles are such that being obtained by liquid-phase process in which at least one metal ion is reduced by a reducing agent in an oxygen-free solution under an inert gas atmosphere.

18. The method of claim 17, wherein a dispersion of the colloidal particles is subjected to at least one of desalting, concentration, purification and dilution.

19. The method of claim 14, wherein said ink further comprises an adsorptive compound or a surfactant in a ratio by weight 0.01 to 2 times the amount of the metal or composite metal.

20. A method for producing a printed circuit board, comprising a step of drawing a pattern on a substrate while supplying droplets of an ink comprising 1 to 80 wt % of colloidal particles which comprise a metal or a composite metal having a specific resistance of 20 μΩ·cm or below at 20° C., and have an average particle size of 1 to 100 nm; and a step of irradiating the substrate having said pattern drawn thereon with laser light or near-field light, thereby generating heat and fusing at least a part of the colloidal particles with the heat, wherein a series of the steps is carried out under an inert gas atmosphere.
